(19) United States
(12) Patent Application Publication
(10) Pub. No.: US 2010/0288625 A1
(43) Pub. Date: Nov. 18, 2010

(54) FILM DEPOSITION APPARATUS AND FILM DEPOSITION METHOD

(75) Inventors: Hajime Nakamura, Chigasaki-shi (JP); Hiroyasu Arima, Chigasaki-shi (JP); Shunichi Imamura, Chigasaki-shi (JP); Kazuya Saito, Chigasaki-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/528,876

(22) PCT Filed: Feb. 25, 2008
(86) PCT No.: PCT/JP2008/053177

§ 371 Date: Aug. 27, 2009

(30) Foreign Application Priority Data
Feb. 28, 2007 (JP) P2007-050646

(51) Int. Cl. C23C 14/34

(52) U.S. Cl. 204/192.1; 204/298.07

(57) ABSTRACT

A film deposition apparatus that deposits a compound thin film on a front surface of a substrate held in a sputter deposition chamber by reactive sputtering, in which the sputter deposition chamber includes a first film quality adjustment gas introduction device that introduces a film quality adjustment gas to a rear surface of the substrate, the film quality adjustment gas adjusting a film quality of a compound thin film deposited on the front surface of the substrate.

### TECHNICAL FIELD

The present invention relates to a film deposition apparatus and a film deposition method, and more particularly to a film deposition apparatus and a film deposition method that are favorably used when a compound thin film such as a transparent conducting thin film is deposited on a front surface of a substrate by reactive sputtering, and that are capable of depositing a compound thin film excellent in in-plane uniformity of film quality.

Priority is claimed on Japanese Patent Application No. 2007-050646 filed on Feb. 28, 2007, the contents of which are incorporated herein by reference.

### BACKGROUND ART OF THE INVENTION

In conventional liquid crystal displays (LCDs), plasma displays (PDPs), and the like, a variety of sputtering apparatuses are proposed for sequentially depositing thin films such as transparent electrodes, dielectric films, insulating films, and the like with a uniform thickness on a multitude of large-area glass substrates.

One of these apparatuses is an inline sputtering apparatus. In this apparatus, a plurality of sputtering cathodes are arranged in a line within its sputter deposition chamber. A carrier on which a substrate is fixed is moved at a constant speed along the orientation direction of the sputtering cathodes. During this process, a target material ejected from a target is deposited on the substrate, to thereby form a desired thin film on the substrate. According to this apparatus, it is possible to sequentially deposit thin films with a uniform thickness on a multitude of glass substrates with a large area (Patent Document 1).

In addition, there is proposed a sputtering apparatus that has rotatable sputtering cathodes formed in a polygonal column shape, in which a target is attached onto each of side surfaces of the sputtering cathodes. In this sputtering apparatus, a target material ejected from the target is deposited on a substrate transferred around the rotating sputtering cathodes, to thereby form desired thin films on the substrate (Patent Document 2). Also in this apparatus, it is possible to sequentially deposit thin films with a uniform thickness on a multitude of large-area glass substrates.

Patent Document 1: Japanese Unexamined Patent Publication, First Publication No. 2002-60938

Patent Document 2: Japanese Unexamined Patent Publication, First Publication No. H06-44836

### DISCLOSURE OF THE INVENTION

### Problems to be Solved by the Invention

In conventional sputtering apparatuses, an inactive gas and a reactive gas are introduced between the target and the glass substrate. However, with a recent increase in the area of such glass substrates, the whole of the film deposition apparatus has increased in size, especially the internal volume of the sputter deposition chamber has increased in size. As a result, not only an amount of the reactive gas and the inactive gas introduced onto the target that are directly exhausted from the space between the substrate and the target increases, but also an amount of the reactive gas and the inactive gas that is exhausted after escaping into the rear surface side of the substrate increases. At this time, the reactive gas and the inactive gas introduced onto the target are diffused from the outer periphery of the substrate to the rear surface side of the substrate and then exhausted. This brings about a local difference in concentration of the introduced inactive gas and the reactive gas on the front surface side of the substrate, resulting in a possible local difference in deposition atmosphere within the plane on the substrate. In that case, there occurs a non-uniform in-plane distribution of film thickness and film quality in the thin film deposited on the substrate. This leads to a problem of variance in characteristics of the obtained transparent electrode, dielectric film, insulating film, and the like within the plane on the substrate.

Furthermore, in the manufacturing process of liquid crystal displays (LCDs), there are cases where a resin film is deposited on a glass substrate and an indium tin oxide (ITO) film is deposited on the resin film. When the ITO film is deposited in the conventional sputtering apparatuses, the film deposition atmosphere of the ITO film is influenced by the gas ejected from the resin film. As a result, there arises a problem in that it is not possible to obtain an ITO film with desired characteristics because of the influence on the film quality of a deposited ITO film.

Furthermore, repetition of the deposition increases an amount of the film deposited on a carrier. Therefore, when this carrier is taken out into the atmosphere, there is a possibility that the thin film deposited on the carrier absorbs moisture in the atmosphere. If this carrier is again used in a film deposition step, the moisture absorbed from the atmosphere is released within the film deposition chamber. This has influence on the film quality of the deposited ITO film. As a result, there arises a problem in that it is not possible to obtain an ITO film with desired characteristics.

Thus, the influence of the gas released from the resin film or the carrier on the film deposition becomes stronger as the substrates are made larger in area, and as the sputtering apparatuses are made larger and speedier in operation.

The present invention has been made in order to solve the above problems, and has an object to provide a film deposition apparatus and a film deposition method that are capable of depositing a compound thin film excellent in in-plane uniformity of film quality in the case of depositing a compound thin film such as a transparent conducting thin film on a front surface of a substrate by reactive sputtering, in which even if deposition is repeated, no gas is released from a carrier, and hence there is no possibility that a film quality of the deposited film is influenced by the released gas.

### Means for Solving the Problem

In order to solve the above-described problems, the present invention employs the following. That is, a film deposition apparatus according to the present invention is a film deposition apparatus that deposits a compound thin film on a front surface of a substrate held in a sputter deposition chamber by reactive sputtering, in which the sputter deposition chamber includes a first film quality adjustment gas introduction device that introduces a film quality adjustment gas to a rear surface of the substrate, the film quality adjustment gas adjusting a film quality of a compound thin film deposited on the front surface of the substrate.

According to the above film deposition apparatus, in a sputter deposition chamber, there is provided a first film quality adjustment gas introduction device that introduces a film quality adjustment gas to a rear surface of a substrate. The film quality adjustment gas adjusts a film quality of a compound thin film deposited on a front surface of the substrate. Therefore, the film quality adjustment gas prevents the reactive gas from escaping from the periphery of the substrate to the rear surface side thereof. Therefore, it is possible to uniform the concentration of the inactive gas and the reactive gas on the front surface side of the substrate. Hence, it is possible to uniform the deposition atmosphere on the substrate. This improves the in-plane uniformity of film thickness and film quality of the deposited film. Consequently, it is possible to make the variance in characteristics of the thin film within the substrate plane extremely small. Furthermore, it is possible to improve the stability of the characteristics.

In addition, in the case of depositing a compound thin film on a resin film, there is no possibility that a film deposition atmosphere of the compound thin film is influenced by a gas released from the resin film. Therefore, there is no possibility that the deposited compound thin film is influenced by the released gas. As a result, it is possible to stabilize the characteristics of the compound thin film.

As described above, it is possible to fabricate a compound thin film with ease and at low cost, the film being extremely low in variance in characteristics within the plane of the substrate, and high in stability in the characteristics.

It may be arranged such that either or both of an anterior chamber for carrying the substrate in the sputter deposition chamber and a posterior chamber for carrying the substrate out of the sputter deposition chamber include a second film quality adjustment gas introduction device that introduces the film quality adjustment gas to the front surface and the rear surface of the substrate.

In this case, a second film quality adjustment gas introduction device that introduces the film quality adjustment gas to the front surface and the rear surface of the substrate is provided in either or both of an anterior chamber for carrying the substrate in the sputter deposition chamber and a posterior chamber for carrying the substrate out of the sputter deposition chamber. Thereby, film deposition atmospheres on both sides of the substrate before and after the deposition process are made uniform. Hence, it is possible to further uniform the film quality and film thickness of the deposited thin film. This enhances the in-plane uniformity of film thickness and film quality of the obtained film. Consequently, it is possible to make the variance in characteristics of the thin film within the substrate plane extremely small. Furthermore, it is possible to improve the stability of the characteristics.

It may be arranged such that the sputter deposition chamber includes: a plurality of carriers each of which holds the substrate, the carriers being arranged in a line along one direction parallel to front surfaces of the substrates; and a gas introduction amount adjustment device that temporally changes an introduction amount of the film quality adjustment gas introduced to the rear surfaces of the substrates when the compound thin film is deposited on the front surfaces of the substrates in a state with the carriers being sequentially moved or being stationary.

In this case, a gas introduction amount adjustment device is used to temporally change an introduction amount of the film quality adjustment gas introduced to the rear surfaces of the substrate, to thereby make it possible to adjust the film quality in correspondence to the temporal change in an amount of released gas at the time of deposition. As a result, it is possible to actualize a stable maintenance of the film quality in sequential deposition on a multitude of substrates.

On the other hand, a film deposition method according to the present invention is a film deposition method of depositing a compound thin film on a front surface of a substrate by reactive sputtering, including: introducing a film quality adjustment gas to a rear surface of the substrate when the compound thin film is deposited under an atmosphere of an inactive gas and a reactive gas.

According to the above-described film deposition method, a film quality adjustment gas is introduced to a rear surface of a substrate when a compound thin film is deposited. Thereby, it is possible to prevent the reactive gas from venting from the periphery of the substrate to the rear surface thereof. Therefore, it is possible to uniform the inactive gas and the reactive gas in concentration on the front surface side of the substrate. Hence, it is possible to uniform the deposition atmosphere on the substrate. This uniforms the film quality and the film thickness of the deposited thin film, and enhances the in-plane uniformity of film thickness and film quality of the obtained film. Consequently, it is possible to make the variance in characteristics of the thin film within the substrate plane extremely small. Furthermore, it is possible to improve the stability of the characteristics.

In addition, in the case of depositing a compound thin film on a resin film, there is no possibility that a film deposition atmosphere of the compound thin film is influenced by a gas released from the resin film. Therefore, there is no possibility that the film quality of the deposited compound thin film is influenced by the released gas. As a result, it is possible to stabilize the characteristics of the compound thin film.

It may be arranged such that the film quality adjustment gas is introduced to the front surface or the rear surface of the substrate at least one of before and after the compound thin film is deposited.

In this case, film deposition atmospheres on both sides of the substrate before and after the deposition are made uniform. Thereby, it is possible to further uniform the film quality and film thickness of the deposited thin film. This further enhances the in-plane uniformity of film thickness and film quality of the obtained film. As a result, it is possible to make the variance in characteristics of the thin film within the substrate plane extremely small. Furthermore, it is possible to improve the stability of the characteristics.

Furthermore, it may be arranged such that a plurality of the substrates are arranged in one direction parallel to the front surfaces of the substrates; and an introduction amount of the film quality adjustment gas introduced to the rear surfaces of the substrates is temporally changed when the compound thin film may be deposited on the front surfaces of the substrates in a state with the substrates being sequentially moved or being stationary.

In this case, an introduction amount of the film quality adjustment gas introduced to the rear surface of the substrate is temporally changed, to thereby make it possible to adjust the film quality in correspondence to the temporal change in an amount of released gas at the time of deposition. As a result, it is possible to actualize stable sequential deposition.

It may be arranged such that an inactive gas is introduced to the rear surface of the substrate when the compound thin film is deposited.

Furthermore, it may be arranged such that a plurality of the substrates are arranged in one direction parallel to the front surfaces of the substrates; and an introduction amount of the inactive gas may be temporally changed when the compound thin film is deposited on the front surfaces of the substrates in a state with the substrates being sequentially moved or being stationary.

### ADVANTAGEOUS EFFECTS OF THE INVENTION

According to the film deposition apparatus of the present invention, in a sputter deposition chamber, there is provided a first film quality adjustment gas introduction device for introducing a film quality adjustment gas to a rear surface of a substrate, the film quality adjustment gas adjusting a film quality of a compound thin film deposited on a front surface of the substrate. Therefore, it is possible to fabricate a compound thin film with ease and at low cost, the film being excellent in film thickness and in-plane uniformity of film quality, extremely low in variance in characteristics within the plane of the substrate, and excellent in stability in the characteristics.

In addition, in the case of depositing a compound thin film on a resin film, there is no possibility that a film deposition atmosphere of the compound thin film is influenced by a gas released from the resin film. Therefore, there is no possibility that the deposited compound thin film is influenced by the released gas. As a result, it is possible to fabricate a compound thin film with stabilized characteristics with ease.

Furthermore, in the case of depositing the compound thin film on the front surfaces of the substrates held on the carriers while moving a plurality of carriers, a gas introduction amount adjustment device is used to temporally change an introduction amount of the film quality adjustment gas introduced to the rear surface of the substrate, to thereby make it possible to adjust the film quality in correspondence to the temporal change in an amount of released gas at the time of deposition. Therefore, it is possible to actualize a stable maintenance of the film quality in sequential deposition.

According to the film deposition method of the present invention, the film quality adjustment gas is introduced to the rear surface of the substrate when the compound thin film is deposited under an inactive gas and reactive gas atmosphere. Thereby, it is possible to prevent the reactive gas from escaping from the periphery of the substrate to the rear surface thereof. Therefore, it is possible to uniform the inactive gas and the reactive gas in concentration within the plane on the front surface side of the substrate. Hence, it is possible to uniform the deposition atmosphere on the substrate. As a result, it is possible to improve the in-plane uniformity of film thickness and film quality of the deposited film. Consequently, it is possible to make the variance in characteristics of the thin film within the substrate plane extremely small. Furthermore, it is possible to improve the stability of the characteristics.

Furthermore, in the case of depositing a compound thin film on a resin film, there is no possibility that a film deposition atmosphere of the compound thin film is influenced by a gas released from the resin film. Therefore, there is no possibility that a deposited compound thin film is influenced by the released gas. As a result, it is possible to stabilize the characteristics of the compound thin film.

### BRIEF DESCRIPTION OF THE DRAWINGS

FIG. 1 is a schematic diagram showing an inline reactive sputtering apparatus according to a first embodiment of the present invention.

FIG. 2 is a side view showing a distribution pipe according to the embodiment.

FIG. 3 is a diagram showing a relationship between a flow rate of O₂ gas per reactive gas introduction pipe on a front substrate surface and a sheet resistance of an ITO thin film.

FIG. 4 is a schematic diagram showing measurement points at which sheet resistance is measured on a front surface of an ITO thin film within a substrate.

FIG. 5 is a diagram showing a relationship between a flow rate of O₂ gas per film quality adjustment gas introduction pipe on a substrate rear surface and a sheet resistance of an ITO thin film.

FIG. 6 is a diagram showing an in-plane variance in sheet resistance of an ITO thin film with reference to an O₂ gas flow rate on a substrate rear surface taken as 0 sccm (0 Pa·m³/s).

FIG. 7 is a diagram showing an in-plane variance in sheet resistance of an ITO thin film with reference to an O₂ gas flow rate on a substrate rear surface taken as 12 sccm (2.03×10⁻² Pa·m³/s) for two film quality adjustment gas introduction pipes.

FIG. 8 is a schematic diagram showing an inline reactive sputtering apparatus according to a second embodiment of the present invention.

FIG. 9 is a schematic diagram showing an inline reactive sputtering apparatus according to a third embodiment of the present invention.

FIG. 10 is a schematic diagram showing an inline reactive sputtering apparatus according to a fourth embodiment of the present invention.

### DESCRIPTION OF THE REFERENCE SYMBOLS

1: sputtering apparatus
2: anterior chamber
3: sputter deposition chamber
4: posterior chamber
5: inlet side zone
6: sputtering zone
7: outlet side zone
11: vacuum pump
12: carrier
14: sputtering cathode
15: target
16: inactive gas introduction pipe
17: reactive gas introduction pipe
18: film quality adjustment gas introduction pipe
21: pipe system
22: narrow pipe portion
23: hole
24: distribution pipe
31: sputtering apparatus
32: sputter deposition chamber
33: sputtering zone
41: sputtering apparatus
42: sputter deposition chamber
43: sputtering zone
51: sputtering apparatus
52: sputter deposition chamber
53, 54: sputtering zone

### BEST MODE FOR CARRYING OUT THE INVENTION

The best mode for carrying out a film deposition apparatus and a film deposition method of the present invention will be described.

This mode is a specific description for better understanding of the spirit or scope of the invention, and hence is not to be considered as limitative of the invention unless otherwise specified.

In the drawings used in the following description, scale ratios among the constituent elements are appropriately modified to make their size recognizable.

In the present embodiments, an inline reactive sputtering apparatus will be described as an exemplary film deposition apparatus.

### First Embodiment

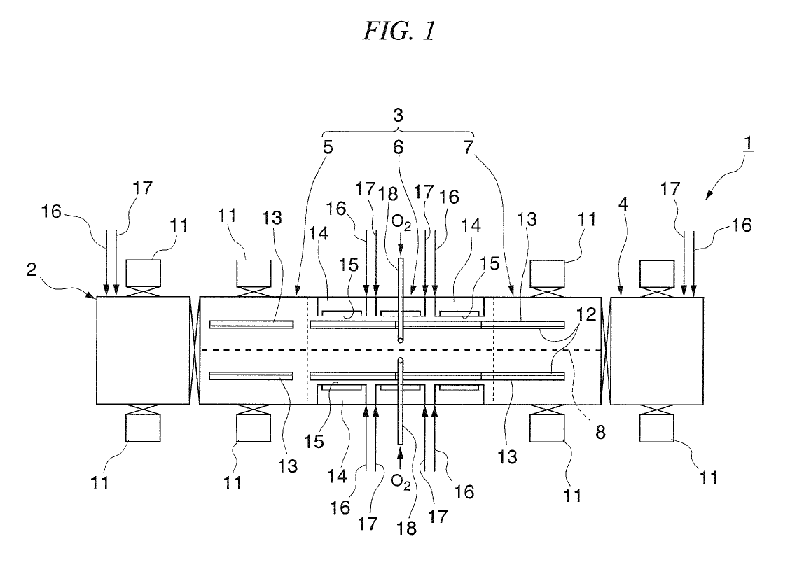

FIG. 1 is a schematic diagram showing an inline reactive sputtering apparatus according to a first embodiment of the present invention.

The sputtering apparatus 1 is made of: an anterior chamber 2; a sputter deposition chamber 3; and a posterior chamber 4, which is also used as a reversing chamber. The sputter deposition chamber 3 is made of three zones: an inlet side zone 5; a sputtering zone 6; and an outlet side zone 7. At a central position in the width direction of the inlet side zone 5, the sputtering zone 6, and the outlet side zone 7, there is provided a partition plate 8 for dividing these zones into two systems: a forward cycle (lower side in FIG. 1) and a return cycle (upper side in FIG. 1).

In the sputtering apparatus 1, the anterior chamber 2 functions as a posterior chamber and the posterior chamber 4 functions as an anterior chamber in the case of the return cycle. Here, for convenience sake, the chambers are referred to as anterior chamber 2 and posterior chamber 4, respectively, with reference to the case of the forward cycle.

There is provided a vacuum pump 11 on each of the anterior chamber 2, the inlet side zone 5 and the outlet side zone 7 of the sputter deposition chamber 3, and the posterior chamber 4. In each of the forward cycle and the return cycle in the zones 2 to 4, a plurality of carriers 12 each for transferring a substrate are arranged so as to be in succession. Each of the carriers 12 is movable in its arrangement direction (in the left-right direction in FIG. 1), and is also fixable at a predetermined position within the zones 2 to 4. At the predetermined position of every carrier 12, a substrate 13 made of glass or the like, on which is to be formed a compound thin film, is held in a manner erected substantially vertically.

On the other hand, on both side walls in the sputtering zone 6, there are provided a plurality of sputtering cathodes 14 along the movement direction of each carrier 12 in both of the forward cycle and the return cycle. To the sputtering cathodes 14, there is attached a target 15, which is a sputtering material for a compound thin film. Each of the targets 15 is positioned so as to be opposed to a front surface of each substrate 13 that is attached at a predetermined position of each carrier 12 with a predetermined distance spaced apart from each other.

Furthermore, in the vicinity of the sputtering cathodes 14, there are arranged: inactive gas introduction pipes 16 for introducing an inactive gas such as Ar; and reactive gas introduction pipes 17 for introducing a reactive gas such as O₂. The pipes are directed toward the carriers 12. On both sides of the central portion of the partition plate 8 in the sputtering zone 6, there is provided a film quality adjustment gas introduction pipe (film quality adjustment gas introduction device) 18 for introducing a film quality adjustment gas such as O₂ to rear surfaces of the substrates 13 held on the carriers 12. The film quality adjustment gas introduction pipe 18 adjusts and uniforms a film deposition atmosphere on front surfaces of the substrates 13 that are carried in the sputtering zone 6.

Furthermore, also in each of the anterior chamber 2 and the posterior chamber 4, there are provided an inactive gas introduction pipe 16 and a reactive gas introduction pipe 17. Note that the number of the inactive gas introduction pipes 16, the reactive gas introduction pipes 17, and the film quality adjustment gas introduction pipes 18 can be set according to the number of the targets 15.

The film quality adjustment gas introduction pipes 18 may be provided in either or both of the anterior chamber 2 and the posterior chamber 4. Furthermore, an inactive gas introduction pipe 16 may be arranged in parallel with the film quality adjustment gas introduction pipe 18, as required.

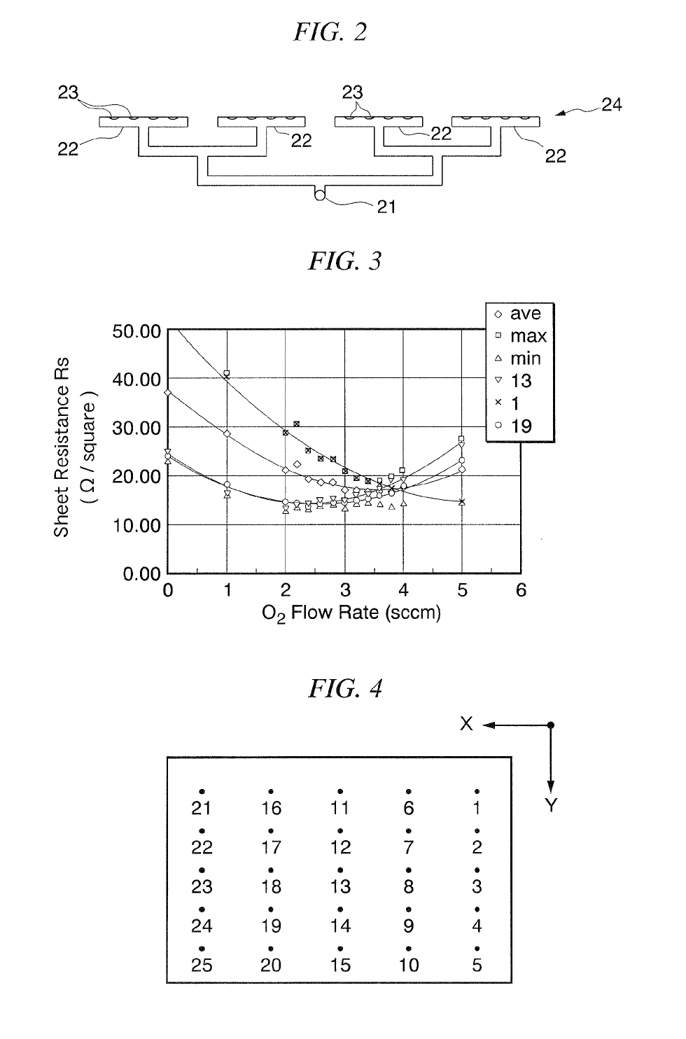

It is permissible that the film quality adjustment gas introduction pipe 18 have a construction that prevents the inactive gas such as Ar and the reactive gas such as O₂ from escaping into the rear surface side of the substrate 13 from the periphery of the carrier 12 that holds the substrate 13, especially from the top and the bottom. For example, as shown in FIG. 2, a distribution pipe 24 referred to as a threefold tournament pipe is preferably used, in which one end portion of a pipe system 21 that is vertically arranged from a ceiling portion (or a bottom portion) of the sputtering zone 6 toward the inside of the chamber is branched in a plurality of steps (two steps in FIG. 2). Long, narrow pipe portions 22 at the tip portions thereof have a multitude of small holes 23 for ejecting a film quality adjustment gas formed along the extension direction thereof, that is, along the transfer direction of the carriers 12 in the sputtering zone 6. Here, a total of two distribution pipes 24 are vertically provided in the sputtering zone 6.

Note that use of ejection nozzles instead of the small holes 23 can offer a similar advantage.

Other than these gas distribution pipes, examples of usable pipes include: a gas ejection pipe in which a small hole for ejecting a film quality adjustment gas is formed at a single location in the long pipe portion that extends in the vertical direction; and a gas ejection pipe in which an ejection nozzle for ejecting a film quality adjustment gas is provided at a single location in the long pipe portion that extends in the vertical direction. In the case of these gas ejection pipes, the film quality adjustment gas is ejected from only one location. Therefore, to uniformly diffuse the film quality adjustment gas toward the periphery of the substrate 13, it is preferable that a diffusing device such as a diffusing plate be provided between the gas ejection pipe and the substrate 13.

Next, a method of depositing a compound thin film on the front surface of the substrate 13 held on the carrier 12 by use of the sputtering apparatus 1 will be described, with reference made to the case of the forward cycle by way of example.

First, a target 15, which is a sputtering material for the compound thin film, is attached to the sputtering cathodes 14 in the sputtering zone 6. The target 15 is appropriately selected according to the compound thin film to be deposited. For example, in the case of an indium tin oxide (ITO) thin film, which is a transparent conducting film, a tin indium alloy target is used. In the case of antimony tin oxide (ATO) thin film, an antimony tin alloy target is used. Furthermore, in the case of a titanium oxide (TiO₂) thin film, which is an optical thin film, a titanium target is used.

In addition, in the case of a magnesium oxide (MgO) thin film, which is a dielectric film, a magnesium target is used.

On the other hand, a carrier 12 is carried in the anterior chamber 2. The anterior chamber 2 is reduced in pressure to a predetermined degree of vacuum by use of the vacuum pump 11. Subsequently, the inactive gas introduction pipe 16 and the reactive gas introduction pipe 17 are used to introduce an inactive gas such as Ar and a reactive gas such as O₂ into the anterior chamber 2, to thereby put the anterior chamber 2 in a mixed gas atmosphere of the inactive gas and the reactive gas with a predetermined pressure.

Subsequently, the sputter deposition chamber 3 including the inlet side zone 5 is decreased in pressure to a predetermined degree of vacuum by use of the vacuum pump 11. Then, the inactive gas introduction pipes 16 and the reactive gas introduction pipes 17 are used to introduce the inactive gas such as Ar and the reactive gas such as O₂ into the sputter deposition chamber 3, to thereby put the sputter deposition chamber 3 including the inlet side zone 5 in a mixed gas atmosphere of the inactive gas and the reactive gas with the predetermined pressure, similarly to the anterior chamber 2.

Subsequently, the carrier 12 is moved from the anterior chamber 2 to the inlet side zone 5. In the inlet side zone 5, the carrier 12 is moved forward so as to be in close contact with another carrier 12 in the direction of movement thereof, to thereby bring the end faces of the adjacent carriers 12 into close contact with each other.

Subsequently, the carriers 12 in close contact with each other are moved to the sputtering zone 6. In the sputtering zone 6, while the carriers 12 are sequentially moved, the film quality adjustment gas introduction pipe 18 is used to eject a film quality adjustment gas such as O₂ onto the rear surfaces of substrates 13 that are held substantially vertically on the carriers 12 under an mixed gas atmosphere of the inactive gas and the reactive gas. As a result, with the atmosphere on the front surfaces (deposition surfaces) of the substrates 13 maintained in a mixed gas atmosphere of the inactive gas and the reactive gas, a compound thin film mainly composed of the target 15 is deposited on the front surfaces of the substrates 13 that are sequentially moved.

In this deposition process, the film quality adjustment gas is ejected onto the rear surface of the substrate 13. This prevents the inactive gas and the reactive gas from escaping into the rear surface side of the substrate 13 from the periphery of the carrier 12, especially from top and bottom, thus uniforming the concentration of the mixed gas within the plane on the front surface side of the substrate 13. Therefore, the deposition atmosphere on the substrate 13 is made uniform. As a result, a compound thin film excellent in in-plane uniformity of film thickness and film quality is deposited on the front surface of the substrate 13.

The flow ratio among the inactive gas, the reactive gas, and the film quality adjustment gas in the deposition process is appropriately set according to the composition and characteristics of the compound thin film to be deposited and to the structure of the film deposition apparatus. Especially, the flow rate of the film quality adjustment gas is required to be a flow rate that prevents the inactive gas and the reactive gas from escaping into the rear surface side of the substrate held on the carrier 12. For example, in the case of an ITO thin film, it is preferable that the flow rate of the film quality adjustment gas be 0.1 to 2 with reference to the total flow rate of the inactive gas and the reactive gas taken as 100.

Subsequently, the first carrier 12 in the line is moved to the outlet side zone 7. The posterior chamber 4 is decreased in pressure to a predetermined degree of vacuum by use of the vacuum pump 11. Subsequently, the inactive gas introduction pipe 16 and the reactive gas introduction pipe 17 are used to introduce an inactive gas such as Ar and a reactive gas O₂ into the posterior chamber 4, to thereby put the posterior chamber 4 in a mixed gas atmosphere of the inactive gas and the reactive gas with a predetermined pressure.

Subsequently, the carrier 12 is moved from the outlet side zone 7 to the posterior chamber 4. In the posterior chamber 4, the carrier 12 is reversed and then transferred toward the anterior chamber 2 again. The deposition in the return cycle is performed exactly in the same manner as in the forward cycle. Also in the return cycle, exactly the same effects and advantages in the forward cycle are obtained. Therefore, the description of the case of the return cycle is omitted.

Finally, the carrier 12 is carried out from the anterior chamber 2, and the substrate 13 is taken out.

As described above, it is possible to fabricate a compound thin film with ease and at a low cost. The film is excellent in in-plane uniformity of film thickness and film quality, extremely low in variance of characteristics within the plane of the substrate, and excellent in stability in the characteristics.

If a film quality adjustment gas introduction pipe 18 is provided in either or both of the anterior chamber 2 and the posterior chamber 4, it is possible to stabilize the deposition atmosphere on the front surface of the substrate before and after the deposition process. In this case, it is possible to further uniform the film quality and the film thickness, and further improve the characteristics of the compound thin film.

Here, while the carriers 12 are sequentially moved in the sputtering zone 6, the compound thin film mainly composed of the target 15 is deposited on the front surfaces of the substrate 13. However, a plurality of carriers 12 may be transferred in the sputtering zone 6 and kept stationary. Then, in this stationary state, the compound thin film mainly composed of the target 15 may be deposited on the front surfaces of the substrates 13. Also in this case, exactly the same advantages are obtained.

Next is a description of experiment results that support special advantages of the film deposition method according to the present embodiment.

The film deposition apparatus of the present embodiment was used to deposit an ITO thin film with a thickness of 150 nm on a glass substrate attached to the carrier 12, under the film deposition condition of room temperature (25° C.).

First, the Ar gas flow rates of the six inactive gas introduction pipes 16 on the front surface (deposition surface) of the glass substrate, with reference to the O₂ gas flow rate on the rear surface of the substrate taken as 0 sccm (0 Pa·m³/s), were set to 400 sccm (0.675 Pa·m³/s). The O₂ gas flow rates of the six reactive gas introduction pipes 17 on the front surface (deposition surface) of the glass substrate were varied so as to be the same in the range of 0 to 5 sccm (0 to 8.4×10⁻³ Pa·m³/s) to deposit a total of 14 types of ITO thin films.

Subsequently, the ITO thin films were heat-treated in the atmosphere at a temperature of 230° C. for one hour.

The sheet resistances of the 14 types of ITO thin films obtained in this manner were measured by the four-terminal method. FIG. 3 shows a relationship between an O₂ gas flow rate per reactive gas introduction pipe 17 on the substrate front surface and a sheet resistance at the time of deposition for the 14 types of ITO thin films. In the figure, 13, 1, and 19 denote three of the numbers assigned to sheet resistance measurement points on the ITO thin film within the substrate shown in FIG. 4. Note that the 25 points shown in FIG. 4 are evenly arranged. Of these measurement points, each of the four points at the corners is positioned 25 mm vertically inside and 25 mm horizontally inside from its corresponding corner. Here, the measurement points are numbered 1 to 25. In FIG. 4, the arrows (←, ⇓) at the top respectively show the X axis direction and the Y axis direction on the ITO thin film.

FIG. 3 shows that the O₂ gas flow rate per reactive gas introduction pipe 17 on the front surface of the glass substrate whose sheet resistance was in the range of 10 to 35 Ω/square was in the range of 2 to 5 sccm (3.4×10⁻³ to 8.4×10⁻³ Pa·m³/s). That is, in the case of six reactive gas introduction pipes 17, the O₂ gas flow rates were in the range of 12 to 30 sccm (2.03×10⁻² to 5.07×10⁻² Pa·m³/s). Furthermore, it was found that if the O₂ gas flow rates on the front surface are in the above range, the in-plane variance in sheet resistance is also small.

Subsequently, the Ar gas flow rates of the six inactive gas introduction pipes 16 on the front surface (deposition surface) of the glass substrate were set to 400 sccm (0.675 Pa·m³/s), and the O₂ gas flow rates of the six reactive gas introduction pipes 17 were set to 2.2 sccm (3.7×10⁻³ Pa·m³/s). Then the O₂ gas flow rates of the two film quality adjustment gas introduction pipes 18 on the rear surface of the substrate were varied so as to be the same in the range of 0 to 20 sccm (0 to 3.38×10⁻² Pa·m³/s) to deposit a total of nine types of ITO thin films.

Subsequently, the ITO thin films were heat-treated in the atmosphere at a temperature of 230° C. for one hour.

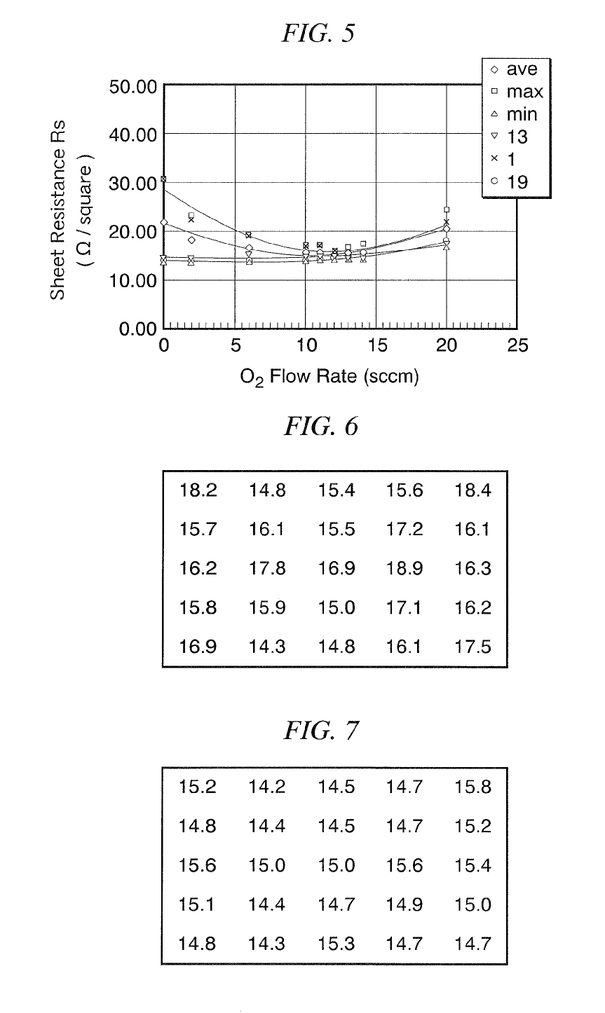

The sheet resistances of the nine types of ITO thin films obtained in this manner were measured by the four-terminal method. FIG. 5 shows a relationship between an O₂ gas flow rate per film quality adjustment gas introduction pipe 18 on the substrate rear surface and a sheet resistance at the time of deposition for the nine types of ITO thin films. In the figure, 13, 1, and 19 denote three of the numbers assigned to resistance measurement points on the ITO thin film shown in FIG. 4.

FIG. 5 shows that as the O₂ gas flow rates on the substrate rear surface were increased, the in-plane variance in sheet resistance was decreased; however, when exceeding a given value, the O₂ gas flow rates on the substrate rear surface began to have an adverse influence on deposition, leading to an increased in-plane variance in sheet resistance.

To check the in-plane variance in sheet resistance, the sheet resistance of the ITO thin film was measured at the measurement points of the ITO thin film shown in FIG. 4 by the four-terminal method, with the O₂ gas flow rate on the substrate rear surface set to 0 sccm (0 Pa·m³/s), the Ar gas flow rate of the six inactive gas introduction pipes 16 on the front surface (deposition surface) of the glass substrate set to 400 sccm (0.675 Pa·m³/s), and the O₂ gas flow rate of the six reactive gas introduction pipes 17 set to 3.6 sccm (6.1×10⁻³ Pa·m³/s). FIG. 6 shows the measurement values corresponding to the measurement points of FIG. 4.

Furthermore, the sheet resistance of the ITO thin film was measured at the measurement points of the ITO thin film shown in FIG. 4 by the four-terminal method, with the O₂ gas flow rate of the two film quality adjustment gas introduction pipes 18 on the rear surface of the substrate set to 12 sccm (2.03×10⁻² Pa·m³/s), the Ar gas flow rate of the six inactive gas introduction pipes 16 on the front surface (deposition surface) of the glass substrate set to 400 sccm (0.675 Pa·m³/s), and the O₂ gas of the six reactive gas introduction pipes 17 set to 2.2 sccm (3.7×10⁻³ Pa·m³/s). FIG. 7 shows the measurement values corresponding to the measurement points of FIG. 4.

Furthermore, variances in sheet resistance within the substrate plane of the ITO thin film shown in FIG. 6 and FIG. 7 were calculated using the following distribution estimation (formula) (1):

(Rₛₘₐₓ−Rₛₘᵢₙ)/(Rₛₘₐₓ+Rₛₘᵢₙ) (1)

where Rₛₘₐₓ represents a maximum value during measurement, and Rₛₘᵢₙ represents a minimum value during measurement.

According to the calculation results, the in-plane variance in sheet resistance of the ITO thin film was ±5% in the case where the O₂ gas was introduced to the rear surface of the substrate, and ±14% in the case where the O₂ gas was not introduced thereto. That is, the in-plane variance in the case where the O₂ gas was introduced to the rear surface of the substrate was half or less of that in the case where the O₂ gas was not introduced thereto. This experiment shows that introduction of the O₂ gas to the rear surface of the substrate can improve the in-plane uniformity of the sheet resistance.

As described above, according to the film deposition method of the present embodiment, it is possible to prevent the reactive gas from escaping from the periphery of the substrate into the rear surface side thereof. Therefore, it is possible to uniform the inactive gas and the reactive gas in concentration on the front surface side of the substrate. Hence, it is possible to uniform the deposition atmosphere on the substrate. As a result, it is possible to improve the in-plane uniformity of film thickness, film quality, and the like. Consequently, it is possible to make the in-plane variance in sheet resistance of the thin film extremely small, and also to improve the stability.

According to the sputtering apparatus 1 of the present embodiment, the film quality adjustment gas introduction pipes 18 for introducing the film quality adjustment gas to the rear surface of the substrate are provided in the sputter deposition chamber 3. Therefore, it is possible to deposit a compound thin film with ease and at a low cost, the film being excellent in in-plane uniformity of film thickness and film quality, extremely low in variance in characteristics within the plane of the substrate, and excellent in stability in the characteristics.

In the case of depositing the compound thin film on the front surfaces of the substrates 12 held on the carriers 13 while moving a plurality of carriers 13, an amount of moisture that is adsorbed on the compound as a component of the thin film attached onto portions of the carriers 13 is gradually increased, and the increase in moisture manifests itself as a temporal change in an amount of released gas at the time of deposition, according to conventional film deposition apparatuses. On the other hand, according to the sputtering apparatus 1 of the present embodiment, the film quality adjustment gas introduction pipes 18 are used to temporally change an introduction amount of film quality adjustment gas introduced to the rear surfaces of the substrates, to thereby make it possible to adjust the film quality in correspondence to the temporal change in an amount of released gas at the time of deposition. As a result, it is possible to actualize a stable maintenance of the film quality in sequential deposition.

### Second Embodiment

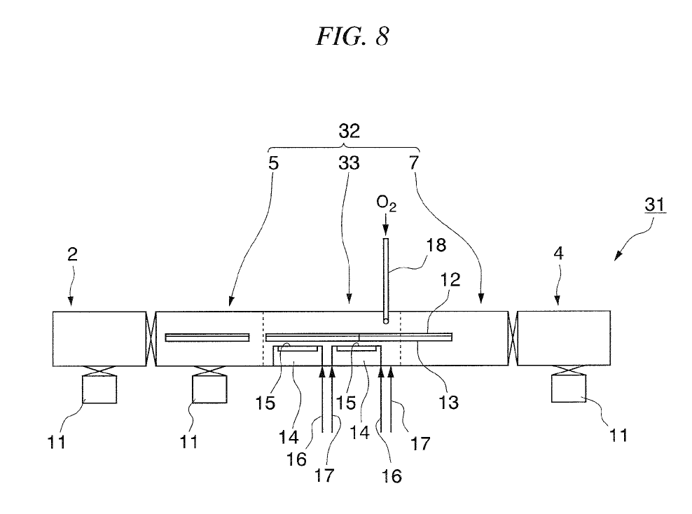

FIG. 8 is a schematic diagram showing an inline reactive sputtering apparatus according to a second embodiment of the present invention. The difference between a sputtering apparatus 31 of the present embodiment and the sputtering apparatus 1 of the first embodiment is as follows. That is, the sputtering apparatus 1 of the first embodiment has a construction in which the carriers 12 are reciprocally transferred, with the vacuum pumps 11 each provided on both sides of each of the inlet side zone 5 and the outlet side zone 7 of the sputter deposition chamber 3, and the film quality adjustment gas introduction pipes 18 each provided at each of the central portions of the sputtering zone 6. On the other hand, the sputtering apparatus 31 of the present embodiment has a construction in which the carriers 12 are transferred only in one direction, with the vacuum pumps 11 each provided on one side of each of the inlet side zone 5 and the outlet side zone 7 of the sputter deposition chamber 32, and the film quality adjustment gas introduction pipe 18 provided in the vicinity of an edge portion of the wall surface, on the side opposite to the vacuum pumps 11, in the sputtering zone 33.

According to the sputtering apparatus 31 of the present embodiment, the film quality adjustment gas introduction pipe 18 is provided in the vicinity of an end portion on the side opposite to the vacuum pumps 11 in the sputtering zone 6. Therefore, even in the construction in which the carriers 12 are transferred only in one direction, it is possible to adjust and uniform a film deposition atmosphere on a front surface of the substrate held on the carrier 12.

### Third Embodiment

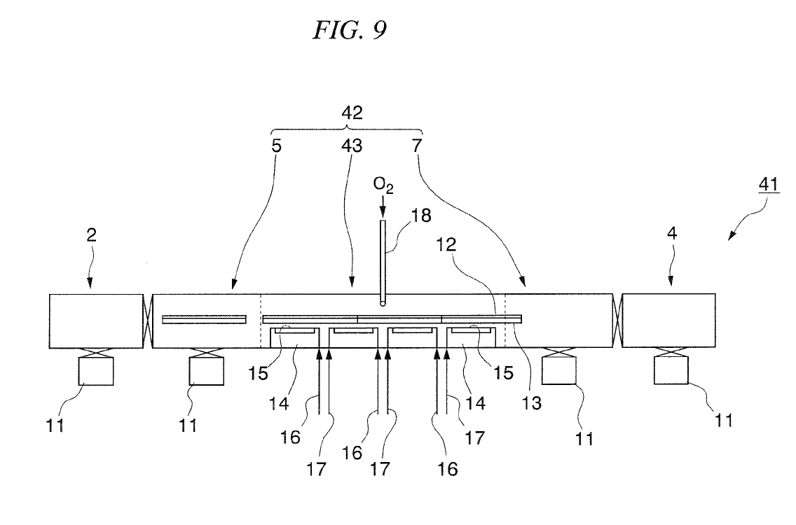

FIG. 9 is a schematic diagram showing an inline reactive sputtering apparatus according to a third embodiment of the present invention. The difference between a sputtering apparatus 41 of the present embodiment and the sputtering apparatus 31 of the second embodiment is as follows. That is, in the sputtering apparatus 31 of the second embodiment, the vacuum pumps 11 are each provided on one side of each of the inlet side zone 5 and the outlet side zone 7, and the film quality adjustment gas introduction pipe 18 is provided in the vicinity of an end portion of the wall surface, on the side opposite to the vacuum pumps 11, in the sputtering zone 33. On the other hand, in the sputtering apparatus 41 of the present embodiment, the vacuum pumps 11 are each provide on one side of each of the inlet side zone 5 and the outlet side zone 7 of the sputter deposition chamber 42, and the film quality adjustment gas introduction pipe 18 is provided at the central portion of the wall surface, on the side opposite to the vacuum pumps 11, in the sputtering zone 43.

According to the sputtering apparatus 41 of the present embodiment, the film quality adjustment gas introduction pipe 18 is provided at the central portion of the wall portion, on the side opposite to the vacuum pumps 11, in the sputtering zone 43. Therefore, even in the construction in which the carriers 12 are transferred only in one direction, it is possible to adjust and uniform a film deposition atmosphere on a front surface of the substrate that is held on the carrier 12.

### Fourth Embodiment

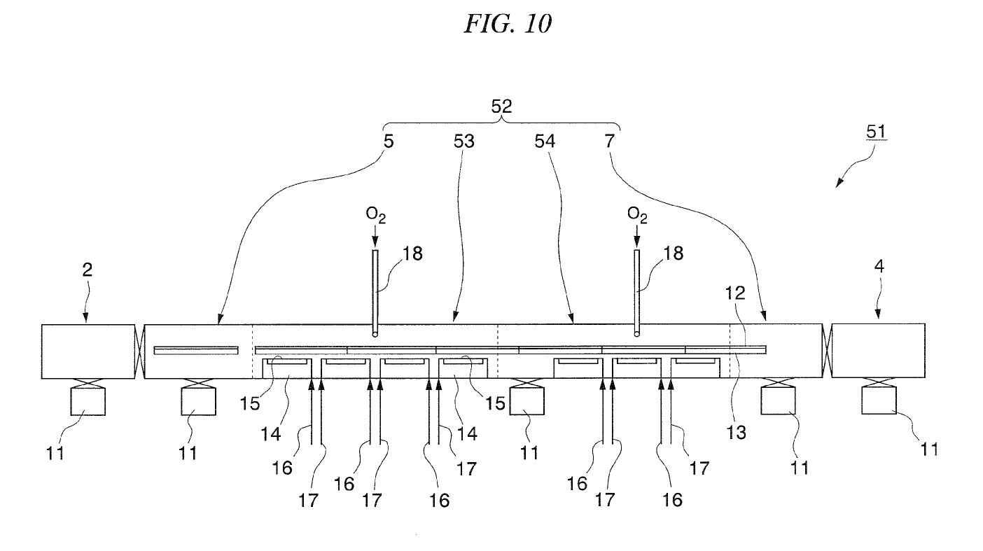

FIG. 10 is a schematic diagram showing an inline reactive sputtering apparatus according to a fourth embodiment of the present invention. The difference between a sputtering apparatus 51 of the present embodiment and the sputtering apparatus 31 of the second embodiment is as follows. That is, in the sputtering apparatus 31 of the second embodiment, the sputtering zone of the sputter deposition chamber 32 is made of a single sputtering zone 33, the vacuum pumps 11 are each provided on one side of each of the inlet side zone 5 and the outlet side zone 7, and the film quality adjustment gas introduction pipe 18 is provided in the vicinity of an end portion of the wall surface, on the side opposite to the vacuum pumps 11, in the sputtering zone 33. On the other hand, in the sputtering apparatus 51 of the present embodiment, the sputtering zone of the sputter deposition chamber 52 is made of a plurality of (two, in FIG. 10) sputtering zones 53 and 54, an additional vacuum pump 11 is provided on one side of an end portion of the sputtering zone 54, and the film quality adjustment gas introduction pipes 18 are each provided at each of the central portions of the wall surfaces, opposite to the vacuum pumps 11, in the sputtering zones 53 and 54.

According to the sputtering apparatus 51 of the present embodiment, an additional vacuum pump 11 is provided on one side of the sputtering zone 54, and the film quality adjustment gas introduction pipes 18 are each provided at each of the central portions of the wall surfaces, opposite to the vacuum pumps 11, in the sputtering zones 53 and 54. Therefore, even in the construction with a plurality of sputtering zones, it is possible to adjust and uniform a film deposition atmosphere on a front surface of the substrate held on the carrier 12.

### INDUSTRIAL APPLICABILITY

According to the present invention, it is possible to provide a film deposition apparatus and a film deposition method that are capable of depositing a compound thin film excellent in in-plane uniformity of film quality in the case of depositing a compound thin film such as a transparent conducting thin film on a front surface of a substrate by reactive sputtering, in which even if deposition is repeated, no gas is released from a carrier, and hence, there is no possibility that a film quality of the deposited film is influenced by the released gas.

What is claimed is:

1. A film deposition apparatus that deposits a compound thin film on a front surface of a substrate held in a sputter deposition chamber by reactive sputtering, wherein the sputter deposition chamber comprises a first film quality adjustment gas introduction device that introduces a film quality adjustment gas to a rear surface of the substrate, the film quality adjustment gas adjusting a film quality of a compound thin film deposited on the front surface of the substrate.

2. The film deposition apparatus according to claim 1, wherein either or both of an anterior chamber for carrying the substrate in the sputter deposition chamber and a posterior chamber for carrying the substrate out of the sputter deposition chamber comprise a second film quality adjustment gas introduction device that introduces the film quality adjustment gas to the front surface and the rear surface of the substrate.

3. The film deposition apparatus according to claim 1, wherein the sputter deposition chamber further comprises:
a plurality of carriers each of which holds the substrate, the carriers being arranged in a line along one direction parallel to the front surfaces of the substrates; and
a gas introduction amount adjustment device that temporally changes an introduction amount of the film quality adjustment gas introduced to the rear surfaces of the substrates when the compound thin film is deposited on the front surfaces of the substrates in a state with the carriers being sequentially moved or being stationary.

4. A film deposition method of depositing a compound thin film on a front surface of a substrate by reactive sputtering, the method comprising introducing a film quality adjustment gas to a rear surface of the substrate when the compound thin film is deposited under an atmosphere of an inactive gas and a reactive gas.

5. The film deposition method according to claim 4, wherein the film quality adjustment gas is introduced to the front surface or the rear surface of the substrate before or after the compound thin film is deposited, or before and after the compound thin film is deposited.

6. The film deposition method according to claim 4, wherein a plurality of the substrates are arranged in one direction parallel to the front surfaces of the substrates and an introduction amount of the film quality adjustment gas introduced to the rear surfaces of the substrates is temporally changed when the compound thin film is deposited on the front surfaces of the substrates in a state with the substrates being sequentially moved or being stationary.

7. The film deposition method according to claim 4, wherein an inactive gas is introduced to the rear surface of the substrate when the compound thin film is deposited.

8. The film deposition method according to claim 7, wherein a plurality of the substrates are arranged in one direction parallel to the front surfaces of the substrates and an introduction amount of the inactive gas is temporally changed when the compound thin film is deposited on the front surfaces of the substrates in a state with the substrates being sequentially moved or being stationary.
